(19) United States
(12) Patent Application Publication
(10) Pub. No.: US 2026/0020190 A1
(43) Pub. Date: Jan. 15, 2026

(54) HEAT DISSIPATION APPARATUS AND HEAT DISSIPATION DEVICE

(71) Applicant: BITMAIN TECHNOLOGIES INC., Beijing (CN)

(72) Inventors: Ketuan ZHAN, Beijing (CN); Zesen NIE, Beijing (CN); Hangkong HU, Beijing (CN); Mingliang HAO, Beijing (CN)

(21) Appl. No.: 18/770,410

(22) Filed: Jul. 11, 2024

(30) Foreign Application Priority Data
May 15, 2023 (CN) 202321165310.X

(51) Int. Cl. H05K 7/20

(52) U.S. Cl. CPC H05K 7/20327; H05K 7/203

(57) ABSTRACT

The present disclosure provides a heat dissipation apparatus for cooling a chipset, including: a sealed liquid cooling tank; a phase-change working medium infused in an interior of the liquid cooling tank; an exhaust port provided in an outer wall of the liquid cooling tank, and the liquid cooling tank is connectable with a sucking pump through the exhaust port; when the sucking pump extracts gas in the liquid cooling tank, air pressure in the liquid cooling tank is reduced from a first value to a second value. The heat dissipation apparatus disclosed in the present application can realize effective heat dissipation of heating devices at a low rated temperature.

### CROSS-REFERENCE TO RELATED APPLICATIONS

The present application claims priority to Chinese Patent Application No. 202321165310.X, filed on May 15, 2023. The aforementioned patent application is hereby incorporated by reference in its entirety.

### TECHNICAL FIELD

The present disclosure relates but is not limited to the technical field of electronic devices, and in particular, to a heat dissipation apparatus and a heat dissipation device.

### BACKGROUND

For phase-change liquid cooling, phase-change cooling liquids are used as heat transfer medium. In a process of heat transfer, a cooling liquid absorbs and releases heat, resulting in phase change, usually accompanied with a small amount of overcooling or overheating, but heat transfer mainly depends on latent heat of phase-change of substances. Where, the immersion-type phase-change liquid cooling technology is used to directly take heat away by phase change of a liquid, which reduces the heat resistance of heat transfer engineering. Compared with the cold-plate-type liquid cooling, the immersion-type phase-change liquid cooling has higher heat transfer efficiency, and is the most energy-saving and efficient refrigeration mode in liquid cooling. However, a system temperature of the immersion-type phase-change liquid cooling depends to a certain extent on a boiling point of a phase-change cooling liquid, which makes it impossible for heating devices, after being operated, to start heat exchanging with the phase-change cooling liquid at a lower system temperature.

### SUMMARY

The present disclosure provides a heat dissipation apparatus and a heat dissipation device to achieve effective heat dissipation of heating devices at a low rated temperature.

In a first aspect, the present disclosure provides a heat dissipation apparatus for cooling a chipset, including: a sealed liquid cooling tank; a phase-change working medium, infused in an interior of the liquid cooling tank; an exhaust port, provided in an outer wall of the liquid cooling tank, and the liquid cooling tank is connectable with a sucking pump through the exhaust port; when the sucking pump extracts gas in the liquid cooling tank, air pressure in the liquid cooling tank is reduced from a first value to a second value.

In some possible embodiments, the second value of the air pressure corresponds to a boiling point of the phase-change working medium.

In some possible embodiments, the exhaust port is a self-sealing connection structure; when the sucking pump extracts gas in the liquid cooling tank through the exhaust port, the self-sealing connection structure is configured to seal the sucking pump and the exhaust port.

In some possible embodiments, at least one outer wall of the liquid cooling tank is provided as a light transmission structure; the light transmission structure is configured to display a liquid level height of the phase-change working medium.

In some possible embodiments, the heat dissipation apparatus further includes a radiator; the radiator is provided on an upper surface of the liquid cooling tank, and an interior of the radiator is communicated with the interior of the liquid cooling tank.

In some possible embodiments, the radiator includes a harmonica tube, and the harmonica tube is a micro-ribbed structure; the harmonica tube is provided on the upper surface of the liquid cooling tank and is communicated with the interior of the liquid cooling tank at the upper surface thereof, and the harmonica tube is used for cooling the phase-change working medium.

In some possible embodiments, the radiator further includes heat dissipation fins; the heat dissipation fins are provided on an outer surface of the harmonica tube. In a second aspect, the present disclosure provides a heat dissipation device, including the liquid cooling tank as described in the first aspect and a chipset; the chipset is provided in the interior of the liquid cooling tank and immersed in the phase-change working medium in the interior of the liquid cooling tank.

In some possible embodiments, a supporting structure is provided between a bottom of the chipset and an inner wall of the liquid cooling tank, and the supporting structure is configured to fix the chipset, and to isolate the bottom of the chipset from the inner wall of the liquid cooling tank.

In some possible embodiments, a power assembly is provided in the interior of the liquid cooling tank, and the power assembly is connected with the chipset and immersed in the phase-change working medium; the power assembly is configured to provide electric energy for the chipset.

In some possible embodiments, the heat dissipation device further includes a cabinet body, and the cabinet body has a first surface and a second surface that are arranged opposite to each other; the heat dissipation device further includes a fan assembly and an air outlet structure, where the fan assembly is provided on the first surface of the cabinet body, and the air outlet structure is provided on the second surface of the cabinet body; the fan assembly is configured to drive air in an interior of the cabinet body to flow and to discharge hot air out of the cabinet body through the air outlet structure.

In some possible embodiments, an upper surface of the chipset is connected with a heat expansion structure, and the heat expansion structure is immersed in the phase-change working medium; the heat expansion structure is configured for heat exchange with the chipset.

In some possible embodiments, the heat expansion structure includes a heat expansion block and surface heat dissipation structures, where the heat expansion block has a first surface and second surfaces, and the second surfaces of the heat expansion block include at least two surfaces except the first surface of the heat expansion block; the first surface of the heat expansion block is connected with the upper surface of the chipset, and the second surfaces of the heat expansion block are provided with the surface heat dissipation structures, respectively; when the chipset generates heat, the chipset is capable of transferring the heat to the heat expansion block, and the heat expansion block transfers the heat to the surface heat dissipation structures; the surface heat dissipation structures transfer the heat to the phase-change working medium, and when a temperature of the phase-change working medium is greater than a boiling point corresponding to an air pressure in the liquid cooling tank, the phase-change working medium is changed from liquid phase to gas phase.

In the present disclosure, the sucking pump extracts gas in the liquid cooling tank, and thus the pressure in the liquid cooling tank is controlled, thereby reducing the boiling point of the phase-change working medium. This achieves effective heat dissipation of heating devices even at a low rated temperature.

It should understandable that the above general description and the later detailed description are only exemplary and explanatory and do not limit the present disclosure.

### BRIEF DESCRIPTION OF DRAWINGS

The drawings herein are incorporated into the specification and form part of the specification, showing embodiments in accordance with the disclosure and, together with the specification, used to explain the principles of the disclosure.

FIG. 1 is a schematic diagram of a structure of a heat dissipation apparatus in an embodiment of the present disclosure.

FIG. 2 is a schematic diagram of a structure of a heat dissipation device in an embodiment of the present disclosure.

FIG. 3 is a schematic diagram of a structure of a heat expansion structure in an embodiment of the present disclosure.

FIG. 4 is the schematic diagram of the structure of several parts of the heat dissipation device in the embodiment of the present disclosure.

### ILLUSTRATION OF REFERENCE NUMBERS

10-heat dissipation apparatus; 11-liquid cooling tank; 12-exhaust port; 13-air-cooled radiator; 111-light transmission structure; 112-aviation plug; 131-heat dissipation fin; 132-harmonica tube; 14-sucking pump; 15-phase-change working medium; 20-heat dissipation device; 21-cabinet body; 22-fan assembly; 23-air outlet structure; 24-chipset; 25-supporting structure; 26-power assembly; 31-heat expansion structure; 311-heat expansion block; 312-surface heat dissipation structure.

### DESCRIPTION OF EMBODIMENTS

The exemplary embodiments will be described in detail here and the examples are shown in the drawings. When the following description refers to the drawings, unless otherwise indicated, the same numbers in different drawings represent the same or similar elements. The implementations described in the following exemplary embodiments do not represent all implementations consistent with the present disclosure. On the contrary, they are only examples of apparatuses consistent with some aspects of the present disclosure as detailed in the appended claims.

After considering the specification and practicing the disclosure disclosed herein, those skilled in the art will easily think of other embodiments of the present disclosure. The present disclosure is aimed to cover any variants, uses or adaptive changes of the present disclosure, these variants, uses or adaptive changes follow the general principles of the present disclosure and include common sense or conventional technical means in the art that is not disclosed herein. The specification and embodiments are only regarded as exemplary, and the true scope and spirit of the present disclosure are indicated by the claims.

In order to illustrate the technical solutions described in the present disclosure, the technical solutions are described below through specific embodiments.

The immersion-type liquid cooling technology is used for heat exchange by immersing heating devices to cause the devices to be contacted with a liquid directly. According to whether mediums have phase change, the immersion-type liquid cooling can be divided into immersion-type single-phase liquid cooling and immersion-type phase-change liquid cooling. In the immersion-type single-phase liquid cooling, a dielectric cooling liquid keeps liquid state. Electronic components are directly immersed in the liquid, the liquid is placed in a sealed but easily accessible container, and heat is transferred from the electronic components to the liquid. A circulating pump is usually used to make the heated cooling liquid flow to a heat exchanger, where it is cooled and recycled back into the container. The cooling liquid remains liquid state with no phase change all the time in a process of circulating heat dissipation. After the low-temperature cooling liquid takes heat away, its temperature rises, and the high-temperature cooling liquid flows to other areas and then cools again to complete the circulation. The immersion-type phase-change liquid cooling uses a phase-change cooling liquid as heat transfer medium, and in the process of heat transfer, the cooling liquid absorbs and releases heat, resulting in phase change, which usually accompanied with a small amount of overcooling or overheating, but mainly depends on latent heat of phase-change of substances. In a system of immersion-type liquid phase-change cooling, a server motherboard, a central processing unit (CPU), a memory and other components with high heat are completely immersed in the cooling liquid; in the working state, respective heating components will generate heat and cause the temperature of the cooling liquid to raise. When the temperature of the cooling liquid rises to a boiling point corresponding to a system pressure, the cooling liquid undergoes phase change from liquid state to gaseous state, and heat is absorbed by heat of vaporization to achieve heat transfer. The immersion-type phase-change liquid cooling technology takes heat away directly by phase-change of the liquid, which reduces heat resistance of heat transfer engineering. Compared with the cold-plate-type liquid cooling, the immersion-type phase-change liquid cooling has higher heat transfer efficiency, and is the most energy-saving and efficient refrigeration mode in liquid cooling.

However, heat dissipation apparatuses using the immersion-type phase-change liquid cooling technology have disadvantages in complexity, integration level, vacuum degree, visualization of their systems and so on. The disadvantages are mainly in that: (1) coil liquid cooling is used at the condensing end, and there is a need to add peripheral devices such as pipes, connectors, water tanks, pumps and so on, resulting in more occupied space and increased project cost; (2) vacuuming is not used for these apparatuses to reduce the vacuum degree of their system, and a lower boiling temperature cannot be used to reduce the temperature level of heating devices; (3) these apparatuses are lack of a visual structure, and thus phenomena of interior boiling and condensation cannot be observed, and thus it is not conducive to the control and study of liquid level height.

In order to solve the above problems, embodiments of the present disclosure provide a heat dissipation apparatus and a heat dissipation device to effectively dissipate heat of heating devices even at a low rated temperature.

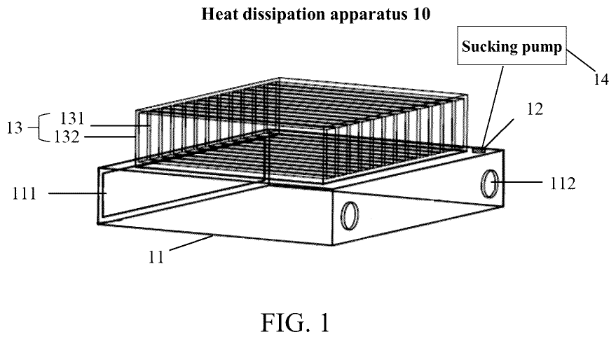

FIG. 1 is a schematic diagram of a structure of a heat dissipation apparatus in an embodiment of the present disclosure. Please refer to FIG. 1, a heat dissipation apparatus 10 includes a sealed liquid cooling tank 11; a phase-change working medium is infused in the liquid cooling tank 11; an exhaust port 12 is provided in an outer wall of the liquid cooling tank 11, and the liquid cooling tank 11 is connectable with a sucking pump through the exhaust port 12; when the sucking pump extracts gas in the liquid cooling tank 11, air pressure in the liquid cooling tank 11 is reduced from a first value to a second value; where the second value corresponds to a boiling point of the phase-change working medium.

It is understandable that the liquid cooling tank 11 is a closed sealed structure, and the exhaust port 12 is provided in the outer wall of the liquid cooling tank 11 (the exhaust port 12 can be one or more in number, which can be set according to actual situations, which is not specifically defined in the embodiment of the present disclosure). The exhaust port 12 runs through inner and outer walls of the liquid cooling tank 11, so that the phase-change working medium can be infused into the interior of the liquid cooling tank 11 through the exhaust port 12 in the outer wall of the liquid cooling tank 11. A heat expansion structure can be provided in the interior of the liquid cooling tank 11, and the heat dissipation apparatus 10 is used to dissipate heat of the heat expansion structure. The liquid level height of the phase-change working medium in the interior of the liquid cooling tank 11 is higher 5-10 mm than a top of the heat expansion structure. In addition to infusing the phase-change working medium into the interior of the liquid cooling tank 11, the exhaust port 12 can also be connected with the sucking pump to extract gas from the liquid cooling tank 11 until the interior of the liquid cooling tank 11 is in a vacuum state (i.e. the air pressure in the liquid cooling tank 11 is reduced from the first value to the second value).

In the embodiment of the present disclosure, using a characteristic of the phase-change working medium that has a lower boiling temperature at a lower pressure, the system temperature level of the heat dissipation apparatus can be reduced by vacuuming through the sucking pump.

In the embodiment of the present disclosure, the phase-change working medium may be one of the following: a fluorinated solution, deionized water, ethanol and methanol. The boiling point range of the phase-change working mediums listed above is 40° C.-100° C. at 1 atmospheric pressure. In addition to the phase-change working mediums listed above, other phase-change working mediums with a boiling point that meets requirements can also be selected, which is not specifically limited in the embodiment of the present disclosure. In order to further illustrate the heat dissipation apparatus 10 in the embodiment of the present disclosure, the fluorinated solution is used as phase-change working medium for example.

In one possible embodiment, the exhaust port 12 may be a self-sealing connection structure; when the sucking pump extracts gas from the liquid cooling tank 11 through the exhaust port 12, the self-sealing connection structure is used to seal the sucking pump and the exhaust port.

It is understandable that in order to ensure an air pressure value in the interior of the liquid cooling tank 11, the exhaust port 12 may be a self-sealing connection structure so that when the sucking pump extracts gas from the liquid cooling tank 11 through the exhaust port 12, gas outside the liquid cooling tank 11 cannot enter the interior of the liquid cooling tank 11 through the connection between the exhaust port 12 and the sucking pump.

In one possible embodiment, at least one outer wall of the liquid cooling tank 11 may be provided as a light transmission structure for displaying the liquid level height of the phase-change working medium, where the light transmission structure can be made of a light transmission material.

It is understandable that in order to facilitate the observation of the liquid level height of the phase-change working medium in the interior of the liquid cooling tank 11, at least one outer wall of the liquid cooling tank 11 is provided with a light transmission structure, and the interior of the liquid cooling tank 11 can be observed through the light transmission structure.

In an example, as shown in FIG. 1, an outer wall of the liquid cooling tank 11 is provided with a light transmission structure 111, which is made of a light transmission material. In the process that the liquid cooling tank 11 is infused with the phase-change working medium, the liquid level height of the phase-change working medium can be observed through the light transmission structure 111.

It should be noted that a situation in which one outer wall of the liquid cooling tank 11 is provided with the light transmission structure 111 in FIG. 1 is only an example, and a plurality of outer walls of the liquid cooling tank 11 may be provided with light transmission structures respectively according to actual needs, which is not limited in the embodiment of the present disclosure.

In the embodiment of the present disclosure, the light transmission structure 111 provided on the liquid cooling tank 11 can be used to observe the liquid level height of the phase-change working medium, ensuring that the liquid level height of the phase-change working medium is higher than that of the heat expansion structure; in addition, the boiling of the phase-change working medium can also be observed. The light transmission structure 111 is sealingly connected with the outer wall of the liquid cooling tank 11 to ensure the air pressure in the interior of the liquid cooling tank 11. The light transmission structure 111 and the liquid cooling tank 11 can be sealingly connected by means of the cooperation of a sealing rubber ring and a glass glue, or other ways of sealing connection, which is not specifically limited in the embodiment of the present disclosure.

In one possible embodiment, the heat dissipation apparatus 10 further includes a radiator; the radiator is provided on the upper surface of the liquid cooling tank 11, and the interior of the radiator is communicated with the interior of the liquid cooling tank.

It should be noted that the radiator in the heat dissipation apparatus 10 can be one of the following: air-cooled radiator, liquid-cooled radiator, heat pipe radiator, air-cooled liquid-cooled compound radiator. The radiator in the embodiment of the present disclosure is not limited to the radiators listed above, but may also be other radiators, which is not limited in the embodiment of the present disclosure. In order to further illustrate the heat dissipation apparatus 10 in the embodiment of the present disclosure, the air-cooled radiator is taken as an example.

It is understandable that, as shown in FIG. 1, an air-cooled radiator 13 is provided above the liquid cooling tank 11, and the air-cooled radiator 13 is integrated with the liquid cooling tank 11, that is, the interior of the air-cooled radiator 13 is communicated with the interior of the liquid cooling tank 11, so that the vaporized phase-change working medium will enter the interior of the air-cooled radiator 13 from the interior of the liquid cooling tank 11, and heat exchange will be carried out in the interior of the air-cooled radiator 13, and thus gaseous working medium condenses into liquid working medium.

In one example, a liquid phase-change working medium (such as a fluorinated solution) is infused into the interior of the liquid cooling tank 11, and the liquid level height of the fluorinated solution in the interior of the liquid cooling tank 11 can be observed through the light transmission structure 111. When electronic devices (such as a chipset) placed in the interior of the liquid cooling tank 11 dissipate a large amount of heat during the electronic devices are running, heat will be transferred to the fluorinated solution which is in direct contact with the chipset, and the fluorinated solution absorbs a large amount of heat. Therefore, at least part of the fluorinated solution will change from liquid state to gaseous state, and the gaseous fluorinated solution in the interior of the liquid cooling tank 11 will rise to the interior of the air-cooled radiator 13 and be in contact with an inner wall of the air-cooled radiator 13. The gaseous fluorinated solution thus transfers heat to the inner wall of the air-cooled radiator 13, and the inner wall of the air-cooled radiator 13 transfers heat to an outer wall of the air-cooled radiator 13 and transfers heat therefrom to external air under an action of air cooling. At this time, the gaseous fluorinated solution in the interior of the air-cooled radiator 13 completes the heat exchange process, and changes from gaseous state to liquid state, and the liquid fluorinated solution will fall into the liquid cooling tank 11 and continue to contact with the chipset, and immerse the chipset. It should be noted that before the running of the chipset, the sucking pump will extract gas in the interior of the liquid cooling tank 11 so that the air pressure in the interior of the liquid cooling tank 11 drops until a negative pressure state. For example, the air pressure in the interior of the liquid cooling tank 11 can be controlled to −0.6 ˜−0.8 MPa by the sucking pump, or it can be set according to actual situations, which is not specifically limited in the embodiment of the present disclosure. Decrease of the air pressure in the interior of the liquid cooling tank 11 will affect the boiling point of the fluorination solution and reduce saturation temperature of the fluorination solution, thereby obtaining a lower system temperature.

In the embodiment of the present disclosure, the air-cooled radiator 13 dissipates heat in the form of direct air cooling, which can significantly reduce system complexity and manufacturing costs, and improve space utilization.

In some possible embodiments, the air-cooled radiator 13 includes a harmonica tube in which a micro-ribbed structure is included; the harmonica tube is provided on the upper surface of the liquid cooling tank 11 and is communicated with the interior of the liquid cooling tank 11 at the upper surface thereof, and the harmonica tube is used to cool the phase-change working medium.

It is understandable that, as shown in FIG. 1, the air-cooled radiator 13 includes a plurality of harmonica tubes 131, and the interior of each harmonica tube 131 is a micro-ribbed structure, this structure can expand the surface area of the harmonica tube 131, and thus greatly increase the heat transfer coefficient of the air-cooled radiator 13. In addition, the harmonica tubes 131 are provided on the upper surface of the liquid cooling tank 11 and are communicated with the interior of the liquid cooling tank 11 at the upper surface thereof.

In the embodiment of the present disclosure, the tops of the harmonica tubes 131 (that is, faces away from the upper surface of the liquid cooling tank 11) may or may not be communicated with each other according to actual needs, which is not specifically limited in the embodiment of the present disclosure.

In some possible embodiments, the air-cooled radiator 13 may further include heat dissipation fins, which are provided on outer surfaces of the harmonica tubes 131.

It is understandable that, as shown in FIG. 1, the air-cooled radiator 13 further includes heat dissipation fins 132 integrated with the harmonica tubes 131, and the heat dissipation fins 132 are provided on the outer surfaces of the harmonica tubes 131 to enhance the heat transfer effect.

In some possible embodiments, an aviation plug may be provided on the outer wall of the liquid cooling tank 11.

It is understandable that, as shown in FIG. 1, when the liquid cooling tank 11 is used to dissipate heat of the chipset and a power assembly, where the chipset is electrically connected to the power assembly, and at this time, the chipset can be electrically connected with the power assembly provided in the liquid cooling tank 11 through the aviation plug 112 to provide electric energy for the power assembly, and to control the power assembly on and off so as to achieve signal transmission.

In one example, when the heat dissipation apparatus 10 dissipates heat of the chipset and the power assembly, the chipset and the power assembly are placed in the interior of the liquid cooling tank 11. Under normal pressure, the fluorinated solution is infused into the sealed liquid cooling tank 11 through the exhaust port 12, and the liquid surface height of the fluorinated solution is observed through the light transmission structure 111 on the liquid cooling tank 11, so that the liquid level of the fluorinated solution is 5-10 mm higher than the upper surface of the heat expansion structure. Then the sucking pump is used to perform cold vacuuming on the liquid cooling tank 11 at the exhaust port 12, so that the air pressure in the interior of the liquid cooling tank 11 is reduced to-0.6 ˜-0.8 MPa. Then the power is turned on so that both the chipset and the power assembly are running, at this time, heat from the chipset and the power assembly will be transferred to the fluorinated solution, the temperature of the fluorinated solution will rise, and the air pressure of the liquid cooling tank 11 will increase slightly. After the above running state is continued for 10 minutes, the power is turned off, and the liquid cooling tank 11 is cooled for 5 minutes, and the sucking pump is used again to perform hot vacuuming on the liquid cooling tank 11, so that the air pressure in the interior of the liquid cooling tank 11 is again reduced to-0.6 ˜-0.8 MPa. The processes of cold vacuuming and hot vacuuming can be carried out repeatedly according to actual needs, which are not specifically limited in the embodiment of the present disclosure. It should be noted that the above cold vacuuming and hot vacuuming will slightly reduce the liquid level height of the fluorination solution, which needs to be observed through the light transmission structure 111, and if necessary, the fluorination solution should be infused in time to ensure the liquid level height; in addition, the type and system pressure of the fluorination solution need to be selected and designed according to the structural space and heat dissipation requirements of the heat dissipation apparatus 10, which is not specifically limited in the embodiment of the present disclosure.

In the embodiment of the present disclosure, the pressure in the interior of the liquid cooling tank can be controlled by extracting gas in the interior of the liquid cooling tank, thereby reducing the boiling point of the phase-change working medium. This achieve effective heat dissipation of heating devices even at a low rated temperature.

Based on a same inventive idea, an embodiment of the present disclosure provides a heat dissipation device including the liquid cooling tank 11 as described in the first aspect and a chipset, and the chipset is provided in the interior of the liquid cooling tank 11 and immersed in the phase-change working medium in the interior of the liquid cooling tank 11.

It is understandable that the chipset, which is a heating electronic device, is placed in the interior of the liquid cooling tank 11, while the liquid cooling tank 11, which is part of the heat dissipation apparatus 10, is provided in the heat dissipation device. It should be noted that the air-cooled radiator 13 in the heat dissipation apparatus 10 is also placed in the interior of the heat dissipation device.

In some possible embodiments, a supporting structure is provided between a bottom of the chipset and the inner wall of the liquid cooling tank 11, and the supporting structure is used for fixing the chipset and isolates the bottom of the chipset from the inner wall of the liquid cooling tank.

It is understandable that when the chipset is placed in the interior of the liquid cooling tank 11, a supporting structure can be provided between the bottom of the chipset and the inner wall of the liquid cooling tank 11, the supporting structure can fix the chipset onto the inner wall of the liquid cooling tank, and the bottom of the chipset is isolated from the inner wall of the liquid cooling tank, that is, the bottom of the chipset is not in direct contact with the inner wall of the liquid cooling tank 11. The chipset maintains a space height of a certain distance from the inner wall of the liquid cooling tank 11 (according to actual need, it can be set to 5˜20 mm), so that the bubble discharge effect at the bottom of the chipset can be enhanced.

In the embodiment of the present disclosure, the supporting structure may be in any of the following forms: bracket, buckle, and bandage. The supporting structure in the embodiment of the present disclosure can also be in other forms, which is not specifically limited in the embodiment of the present disclosure.

In some possible embodiments, a power assembly is further provided in the interior of the liquid cooling tank 11, and the power assembly is connected to the chipset and immersed in the phase-change working medium; the power assembly is used to provide power for the chipset.

It is understandable that, in addition to the chipset, a power module can also be placed in the interior of the liquid cooling tank 11, and the power assembly is used to provide electric energy for the chipset and is immersed in the phase-change working medium together with the chipset. In the process of operation, the power assembly will also generate heat and make heat exchange with the phase-change working medium just like the chipset since the power assembly is placed in the phase-change working medium, so as to achieve the purpose of heat dissipation.

In the embodiment of the present disclosure, the integrated design in which the power assembly is embedded in the liquid cooling tank 11 can improve the system integration without considering the heat dissipation of the power assembly separately. In addition, the chipset and the power assembly can be fixed in the interior of the liquid cooling tank 11 according to actual needs, and the fixing method can adopt a positioning mode of the matching of a slide rail and a screw or other positioning modes, which is not specifically limited in the embodiment of the present disclosure.

It should be noted that the chipset and the power assembly can be provided side by side, or the power assembly can be placed above or below the chipset, as long as it is ensured that the power assembly and the chipset are completely immersed in the phase-change working medium, this is not specifically limited in the embodiment of the present disclosure.

In some possible embodiments, the heat dissipation device further includes a cabinet body, and the cabinet body has a first surface and a second surface that are arranged opposite to each other; the heat dissipation device further includes a fan assembly and an air outlet structure, where the fan assembly is provided on the first surface of the cabinet body, and the air outlet structure is provided on the second surface of the cabinet body; the fan assembly is used to drive air in the interior of the cabinet body to flow so as to discharge hot air out of the cabinet body through the air outlet structure.

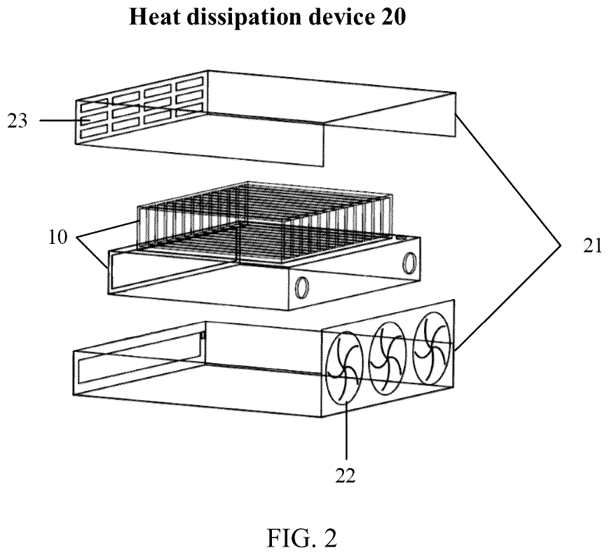

It is understandable that, FIG. 2 is a schematic diagram of a structure of a heat dissipation device in an embodiment of the present disclosure, as shown in FIG. 2, a heat dissipation device 20 includes a cabinet body 21, and an interior of the cabinet body 21 is provided with a heat dissipation apparatus 10. The heat dissipation device 20 includes a fan assembly 22 and an air outlet structure 23 that are oppositely provided on the heat dissipation device 20 (that is, a first surface and a second surface of the heat dissipation device 20), where the fan assembly 22 is used to drive air in the interior of the cabinet body 21 to flow, and the coordinating of the fan assembly 22 and the air outlet structure 23 provided on the other side of the cabinet body 21 can make hot air in the air-cooled radiator 13 discharge out of the cabinet body 21.

In some possible embodiments, an upper surface of the chipset is connected with a heat expansion structure, and the heat expansion structure is immersed in the phase-change working medium; the heat expansion structure is used for heat exchange with the chipset.

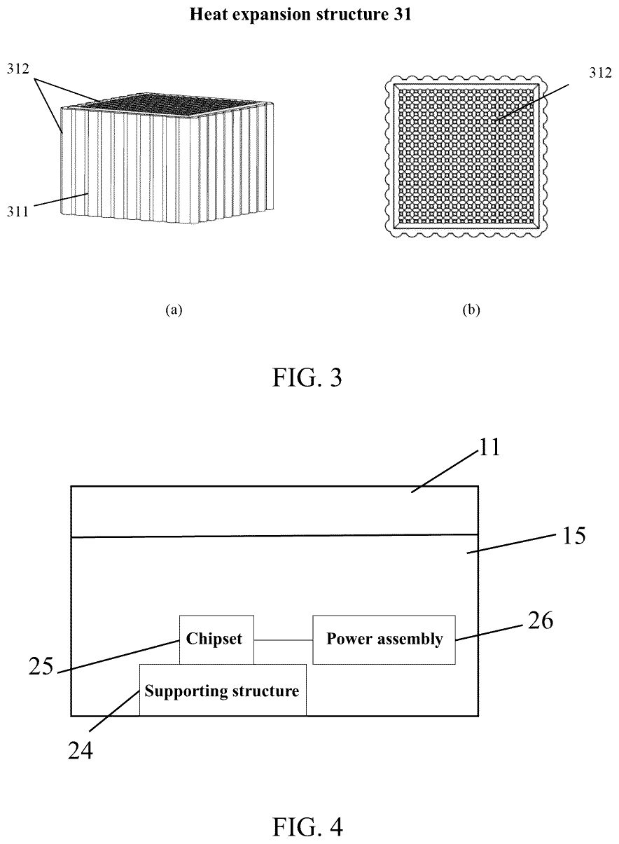

It is understandable that FIG. 3 is a schematic diagram of a structure of a heat expansion structure in an embodiment of the present disclosure, where (a) in FIG. 3 is a perspective view of the heat expansion structure, and (b) in FIG. 3 is a top view of the heat expansion structure. As shown in FIG. 3, the upper surface of the chipset is connected with the heat expansion structure 31, and the heat expansion structure 31 is in direct contact with the chipset and can be heat exchanged with the chipset. At the same time, the heat expansion structure 31 has a surface area larger than that of the chipset, resulting in an increased contact area with the phase-change working medium, thereby improving the heat dissipation effect. It should be noted that the heat expansion structure 31 is immersed in the phase-change working medium together with the chipset.

In the embodiment of the present disclosure, the heat expansion structure 31 may be made of a metal with a higher heat conductivity coefficient, such as copper or aluminum, and the specific metal material may be selected according to actual needs, which is not specifically limited in the embodiment of the present disclosure.

In some possible embodiments, the heat expansion structure 31 includes a heat expansion block and surface heat dissipation structures, where the heat expansion block has a first surface and second surfaces, and the second surfaces of the heat expansion block include at least two surfaces except the first surface of the heat expansion block; the first surface of the heat expansion block is connected with the upper surface of the chipset, and the second surfaces of the heat expansion block are provided with the surface heat dissipation structures, respectively; when the chipset generates heat, the chipset is capable of transferring heat to the heat expansion block, and the heat expansion block transfers heat to the surface heat dissipation structures; the surface heat dissipation structures transfer heat to the phase-change working medium, and when a temperature of the phase-change working medium is greater than a boiling point corresponding to an air pressure in the liquid cooling tank, the phase-change working medium is changed from liquid phase to gas phase.

In one example, as shown in FIG. 3, the heat expansion structure 31 includes a heat expansion block 311 and surface heat dissipation structures 312. A surface of the heat expansion block 311 in contact with the upper surface of the chipset is the first surface of the heat expansion block 311, and other five surfaces of the heat expansion block 311 except the first surface are all second surfaces (it should be noted that the situation in which the second surfaces of the heat expansion block 311 are other five surfaces except the first surface is only an example, the number of the second surfaces can be specifically set according to actual situations, which is not specifically limited in the embodiment of the present disclosure). The second surfaces of the heat expansion block 311 (that is, the other five surfaces except the first surface) are provided with surface heat dissipation structures 312, the surface heat dissipation structures 312 are not in direct contact with the upper surface of the chipset. The surface heat dissipation structures 312 are sprayed with copper powder, so that vaporization nucleation sites can be increased, thereby enhancing boiling heat exchange effect. When the chipset immersed in the phase-change working medium is running, the chipset radiates a large amount of heat and transfers heat to the first surface of the heat expanding block 311 through the upper surface of the chipset, the first surface of the heat expanding block 311 then transfers heat through the second surfaces to the surface heat dissipation structures 312. Surfaces of the surface heat dissipation structures 312 have a certain roughness, so that the surface area of the surface heat dissipation structures 312 is larger, and thus the heat from the chipset can be quickly transferred to the phase-change working medium.

In the embodiment of the present disclosure, the second surfaces of the heat expanding block 311 can be provided in a wavy shape, thereby increasing the surface area of the heat expanding block 311, and thus enhancing the boiling heat exchange effect, and effectively reducing the temperature of the heating device (that is, the chipset).

In the embodiment of the present disclosure, the first surface of the heat expansion block 311 and the upper surface of the chipset may be connected by a heat conducting medium in cooperation with mechanical fixation or welding, and if the connection is made by welding, the first surface of the heat expansion block 311 needs to be subjected to descaling treatment.

In some possible embodiments, the surface heat dissipation structures 312 may be subjected to surface special process treatment.

In one example, in order to enhance boiling vaporization nucleation sites, the surface heat dissipation structures 312 are subjected to surface special process treatment, and the surface special process treatment may include one of the following: copper powder sintering, copper mesh bonding and copper powder spraying, where if the copper powder sintering is adopted, copper powder has a particle size of 10˜500 μm can be selected; if the copper mesh bonding is adopted, the copper mesh has a mesh number of 200˜800 can be selected; if the copper powder spraying is adopted, copper powder has a particle size of 10˜500 μm can be selected, and the spraying pressure can be 0.4˜2 Mpa. The surface heat dissipation structures 312 subjected to the surface special process treatment can form a surface morphology with an overall thickness of 25˜150 μm and a pore diameter of 50˜600 μm.

It should be noted that specific process parameters involved in the surface special process for treating the surface heat dissipation structures 312 can be designed according to actual needs, which is not specifically limited in the embodiment of the present disclosure.

In the embodiment of the present disclosure, the second surfaces of the heat expanding block 311 are treated by a surface special process (that is, copper powder spray process) to form a surface morphology with high adhesion strength and controllable roughness, resulting in increased number of vaporization nucleation sites, and strengthening boiling heat exchange effect. In addition, this process not only has higher adhesion strength than copper powder sintering and copper mesh bonding, but also can achieve different surface morphology of different roughness by adjusting particle size of copper powder and spraying pressure, thereby enhancing the boiling heat exchange effect.

The manufacturing process of the heat expansion structure 31 is described below to further illustrate the heat dissipation device in the embodiment of the present disclosure.

As an example, firstly, the heat expansion block 311 is designed according to the size and heat flux density of the heating device (that is, the chipset), and its length and width are greater than or equal to the length and width of the chipset. Here, it is considered that the heat expansion block is electrically isolated from other devices on the chipset, the same length-width design is used, for example, the size of the heat expansion block is 8 mm (L)×8 mm (W)×5 mm (H). Then the copper with good heat conductivity coefficient (red copper with density of 8.96 g/cm³, heat conductivity coefficient of 400W/m· K, specific heat capacity of 390 J/kg· K) is used to process the heat expansion block 311, and all the surfaces of the heat expansion block 311 are subjected to descaling treatment. Then the second surfaces of the heat expansion block 311 are processed by copper powder spraying, where the particle size of copper powder is 50 μm and the spraying pressure is 1 MPa. Then the first surface of the heat expanding block 311 in contact with the upper surface of the chipset is then subjected to secondary descaling treatment and welded with the upper surface of the chipset.

Those skilled in the art can understand that the size of the serial numbers of the steps in the above embodiment does not mean execution order, and the execution order of respective processes should be determined by their function and inherent logic, and should not constitute any limitation on the implementation process of the embodiments of the present disclosure.

The above embodiments are only used to illustrate the technical solutions of the present disclosure, not to limit them. Although the present disclosure has been described in detail with reference to the aforementioned embodiments, those skilled in the art should understand that they may still make modifications to the technical solutions described in the aforementioned embodiments, or make equivalent substitutions to some technical features thereof. These modifications or substitutions do not deviate the nature of the corresponding technical solutions from the spirit and scope of the technical solutions of the embodiments of the present disclosure and shall be included in the scope of protection of the present disclosure.

What is claimed is:

1. A heat dissipation apparatus for cooling a chipset, comprising:
a sealed liquid cooling tank;
a phase-change working medium, infused in an interior of the liquid cooling tank;
an exhaust port, provided in an outer wall of the liquid cooling tank, and the liquid cooling tank is connectable with a sucking pump through the exhaust port;
when the sucking pump extracts gas in the liquid cooling tank, air pressure in the liquid cooling tank is reduced from a first value to a second value.

2. The heat dissipation apparatus according to claim 1, wherein the second value corresponds to a boiling point of the phase-change working medium.

3. The heat dissipation apparatus according to claim 1, wherein the exhaust port is a self-sealing connection structure;
when the sucking pump extracts gas in the liquid cooling tank through the exhaust port, the self-sealing connection structure is configured to seal the sucking pump and the exhaust port.

4. The heat dissipation apparatus according to claim 1, wherein at least one outer wall of the liquid cooling tank is provided as a light transmission structure;
the light transmission structure is configured to display a liquid level height of the phase-change working medium.

5. The heat dissipation apparatus according to claim 1, wherein the heat dissipation apparatus further comprises a radiator;
the radiator is provided on an upper surface of the liquid cooling tank, and an interior of the radiator is communicated with the interior of the liquid cooling tank.

6. The heat dissipation apparatus according to claim 5, wherein the radiator comprises a harmonica tube, and the harmonica tube is a micro-ribbed structure;
the harmonica tube is provided on the upper surface of the liquid cooling tank and is communicated with the interior of the liquid cooling tank at the upper surface thereof.

7. The heat dissipation apparatus according to claim 6, wherein the radiator further comprises heat dissipation fins;
the heat dissipation fins are provided on an outer surface of the harmonica tube.

8. A heat dissipation device, comprising the liquid cooling tank according to claim 1 and a chipset;
the chipset is provided in the interior of the liquid cooling tank and immersed in the phase-change working medium in the interior of the liquid cooling tank.

9. The heat dissipation device according to claim 8, wherein the second value corresponds to a boiling point of the phase-change working medium.

10. The heat dissipation device according to claim 8, wherein the exhaust port is a self-sealing connection structure;
when the sucking pump extracts gas in the liquid cooling tank through the exhaust port, the self-sealing connection structure is configured to seal the sucking pump and the exhaust port.

11. The heat dissipation device according to claim 8, wherein at least one outer wall of the liquid cooling tank is provided as a light transmission structure;
the light transmission structure is configured to display a liquid level height of the phase-change working medium.

12. The heat dissipation device according to claim 8, wherein the heat dissipation apparatus further comprises a radiator;
the radiator is provided on an upper surface of the liquid cooling tank, and an interior of the radiator is communicated with the interior of the liquid cooling tank.

13. The heat dissipation device according to claim 12, wherein the radiator comprises a harmonica tube, and the harmonica tube is a micro-ribbed structure;
the harmonica tube is provided on the upper surface of the liquid cooling tank and is communicated with the interior of the liquid cooling tank at the upper surface thereof.

14. A heat dissipation device according to claim 13, wherein the radiator further comprises heat dissipation fins;
the heat dissipation fins are provided on an outer surface of the harmonica tube.

15. The heat dissipation device according to claim 8, wherein a supporting structure is provided between a bottom of the chipset and an inner wall of the liquid cooling tank, and the supporting structure is configured to fix the chipset, and to isolate the bottom of the chipset from the inner wall of the liquid cooling tank.

16. The heat dissipation device according to claim 8, wherein a power assembly is provided in the interior of the liquid cooling tank, and the power assembly is connected with the chipset and immersed in the phase-change working medium;
the power assembly is configured to provide electric energy for the chipset.

17. The heat dissipation device according to claim 8, wherein the heat dissipation device further comprises a cabinet body, and the cabinet body has a first surface and a second surface that are arranged opposite to each other;
the heat dissipation device further comprises a fan assembly and an air outlet structure, wherein the fan assembly is provided on the first surface of the cabinet body, and the air outlet structure is provided on the second surface of the cabinet body;
the fan assembly is configured to drive air in an interior of the cabinet body to flow so as to discharge hot air out of the cabinet body through the air outlet structure.

18. The heat dissipation device according to claim 8, wherein an upper surface of the chipset is connected with a heat expansion structure, and the heat expansion structure is immersed in the phase-change working medium;
the heat expansion structure is configured for heat exchange with the chipset.

19. The heat dissipation device according to claim 18, wherein the heat expansion structure comprises a heat expansion block and surface heat dissipation structures, wherein the heat expansion block has a first surface and second surfaces, and the second surfaces of the heat expansion block comprise at least two surfaces except the first surface of the heat expansion block;
the first surface of the heat expansion block is connected with the upper surface of the chipset, and the second surfaces of the heat expansion block are provided with the surface heat dissipation structures, respectively;
when the chipset generates heat, the chipset transfers the heat to the heat expansion block, and the heat expansion block transfers the heat to the surface heat dissipation structures; the surface heat dissipation structures transfer the heat to the phase-change working medium, and when a temperature of the phase-change working medium is greater than a boiling point corresponding to an air pressure in the liquid cooling tank, the phase-change working medium is changed from liquid phase to gas phase.
